(19) United States
(12) Patent Application Publication
(10) Pub. No.: US 2011/0068367 A1
(43) Pub. Date: Mar. 24, 2011

(54) DOUBLE-SIDED HETEROJUNCTION SOLAR CELL BASED ON THIN EPITAXIAL SILICON

(75) Inventors: Jiunn Benjamin Heng, San Jose, CA (US); Chentao Yu, Sunnyvale, CA (US); Zheng Xu, Pleasanton, CA (US); Andrew Komrowski, Fremont, CA (US)

(73) Assignee: SIERRA SOLAR POWER, INC., Fremont, CA (US)

(21) Appl. No.: 12/881,010

(22) Filed: Sep. 13, 2010

Related U.S. Application Data
(60) Provisional application No. 61/244,921, filed on Sep. 23, 2009.

(51) Int. Cl. H01L 31/0264; H01L 21/20

(52) U.S. Cl. 257/184; 438/94; 257/E31.004; 257/E21.09

(57) ABSTRACT

One embodiment of the present invention provides a double-sided heterojunction solar cell. The solar cell includes a lightly doped epitaxial crystalline Si (c-Si) base layer, a front-side passivation layer situated on the front side of the lightly doped epitaxial c-Si base layer, a back-side passivation layer situated on the back side of the lightly doped epitaxial c-Si base layer, a front-side emitter situated on the surface of the front-side passivation layer, a back surface field (BSF) layer situated on the surface of the back-side passivation layer, a front-side electrode, and a back-side electrode.

### RELATED APPLICATION

This application claims the benefit of U.S. Provisional Application No. 61/244,921, Attorney Docket Number SSP09-1013PSP, entitled “Double-Sided Heterojunction Solar Cell Based on Thin Epitaxial Silicon,” by inventors Jiunn Benjamin Heng, Chentao Yu, Zheng Xu, Peijun Ding, Andrew Komrowski, and Wen Ma, filed 23 Sep. 2009.

### BACKGROUND

1. Field

This disclosure is generally related to solar cells. More specifically, this disclosure is related to a double-sided heterojunction solar cell based on thin epitaxial silicon.

2. Related Art

The negative environmental impact caused by the use of fossil fuels and their rising cost have resulted in a dire need for cleaner, cheaper alternative energy sources. Among different forms of alternative energy sources, solar power has been favored for its cleanness and wide availability.

A solar cell converts light into electricity using the photoelectric effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi junction structure includes multiple single junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit.

For homojunction solar cells, minority-carrier recombination at the cell surface due to the existence of dangling bonds can significantly reduce the solar cell efficiency; thus, a good surface passivation process is needed. In addition, the relatively thick, heavily doped emitter layer, which is formed by dopant diffusion, can drastically reduce the absorption of short wavelength light. Comparatively, heterojunction solar cells, such as Si heterojunction (SHJ) solar cells, are advantageous. FIG. 1 presents a diagram illustrating an exemplary SHJ solar cell (prior art). SHJ solar cell 100 includes front electrodes 102, an n⁺ amorphous-silicon (n⁻ a-Si) emitter layer 104, an intrinsic a-Si layer 106, a p-type doped crystalline-Si (c-Si) substrate 108, and an Al back-side electrode 110. Arrows in FIG. 1 indicate incident sunlight. Because there is an inherent bandgap offset between a-Si layer 106 and c-Si layer 108, a-Si layer 106 can be used to reduce the surface recombination velocity by creating a barrier for minority carriers. The a-Si layer 106 also passivates the surface of c-Si layer 108 by repairing the existing Si dangling bonds through hydrogenation. Moreover, the thickness of n⁺ a-Si emitter layer 104 can be much thinner compared to that of a homojunction solar cell. Thus, SHJ solar cells can provide a higher efficiency with higher open-circuit voltage (V_{oc}) and larger short-circuit current (J_{sc}).

Fuhs et al. first reported a hetero-structure based on a-Si and c-Si that generates photocurrent in 1974 (see W. Fuhs et al., “Heterojunctions of Amorphous Silicon & Silicon Single Crystal,” Int. Conf., Tetrahedrally Bonded Amorphous Semiconductors, Yorktown Hts., N.Y., (1974), pp. 345-350). U.S. Pat. No. 4,496,788 disclosed a heterojunction type solar cell based on stacked a-Si and c-Si wafers. The so-called HIT (heterojunction with intrinsic thin layer) solar cell, which includes an intrinsic a-Si layer interposed between a-Si and c-Si layers, was disclosed by U.S. Pat. No. 5,213,628. However, all these SHJ solar cells are based on a crystalline-Si substrate whose thickness can be between 200 μm and 300 μm. Due to the soaring cost of Si material, the existence of such a thick c-Si substrate significantly increases the manufacture cost of existing SHJ solar cells. To solve the problem of the high cost incurred by c-Si wafers, a solution is to epitaxially grow a c-Si thin film on a low-cost MG-Si wafer, thus eliminating the need for c-Si wafers. However, such an approach has its own limitations in terms of solar cell efficiency. In a heterojunction solar cell with MG-Si substrate, the light passing through the active epitaxial c-Si film will be subsequently absorbed by the MG-Si substrate, thus limiting J_{sc}. In addition, the lack of effective passivation between the back surface of the c-Si film and the MG-Si substrate limits the open circuit voltage (V_{oc}) as well as J_{sc} due to the significant back surface minority-carrier recombination. Moreover, it provides limited temperature coefficient improvement, which is related to V_{oc} in terms of junction recombination centers, interface defects, metal impurities, etc.

### SUMMARY

One embodiment of the present invention provides a double-sided heterojunction solar cell. The solar cell includes a lightly doped epitaxial crystalline Si (c-Si) base layer, a front-side passivation layer situated on the front side of the lightly doped epitaxial c-Si base layer, a back-side passivation layer situated on the back side of the lightly doped epitaxial c-Si base layer, a front-side emitter situated on the surface of the front-side passivation layer, a back surface field (BSF) layer situated on the surface of the back-side passivation layer, a front-side electrode, and a back-side electrode.

In a variation on the embodiment, at least one surface of the lightly doped epitaxial c-Si layer is textured.

In a variation on the embodiment, the solar cell further includes at least one transparent conductive oxide (TCO) layer situated on the surface of the front-side emitter and/or the surface of the BSF layer.

In a variation on the embodiment, the passivation layers comprise intrinsic amorphous Si (a-Si) or silicon-oxide (SiOₓ).

In a variation on the embodiment, the thickness of the passivation layers is between 2 nm and 8 nm.

In a variation on the embodiment, the front-side emitter and/or the BSF layer comprise heavily doped a-Si.

In a further variation, the thickness of the a-Si front-side emitter and/or the BSF layer is between 5 nm and 50 nm, wherein the doping concentration of the heavily doped a-Si is between 1×10¹⁷/cm³ and 1×10²⁰/cm³.

In a variation on the embodiment, the lightly doped epitaxial c-Si layer is deposited using a chemical-vapor-deposition (CVD) technique, the thickness of the lightly doped epitaxial c-Si layer is between 20 μm and 100 μm, and the doping concentration for the lightly doped epitaxial c-Si layer is between 1×10¹⁵/cm³ and 1×10¹⁷/cm³.

In a variation on the embodiment, the lightly doped c-Si layer is n-type doped, wherein the front-side emitter and the BSF layer are doped with different types of dopants.

In a variation on the embodiment, the front-side and the back-side passivation layers are formed in one step.

In a variation on the embodiment, the front-side emitter and the BSF layer are formed in one step.

In a variation on the embodiment, the lightly doped epitaxial c-Si layer is epitaxially grown on a metallurgical-grade Si (MG-Si) substrate, which is subsequently removed using a mechanical grinding technique.

### BRIEF DESCRIPTION OF THE FIGURES

FIG. 1 presents a diagram illustrating an exemplary SHJ solar cell (prior art).

FIG. 2 presents a diagram illustrating the process of fabricating a double-sided heterojunction solar cell in accordance with an embodiment of the present invention.

FIG. 3 presents a diagram illustrating the process of fabricating a double-sided heterojunction solar cell in accordance with an embodiment of the present invention.

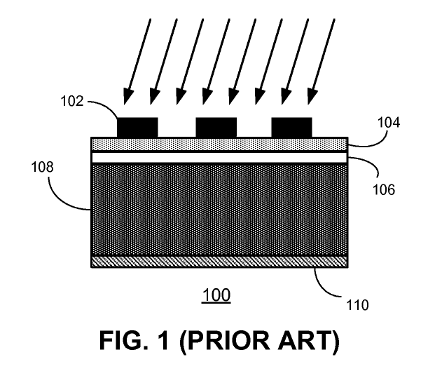

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a double-sided heterojunction solar cell based on thin epitaxial silicon. The high-efficiency double-sided heterojunction solar cell can be fabricated by epitaxially growing an ultra-thin layer of heavily doped crystalline silicon (c-Si), acting as an impurity-getter layer, and a thin layer of lightly doped c-Si, acting as a base film, on top of a metallurgical-grade silicon (MG-Si) substrate. The MG-Si substrate and the heavily doped c-Si impurity-getter layer are then removed, and the front and back surfaces of the remaining c-Si base film are cleaned. Subsequently, an amorphous-Si (a-Si) layer stack, which includes a thin layer of intrinsic a-Si and a thin layer of n⁺ or p⁺ a-Si, is deposited on both sides of the c-Si base film to form the n or p emitter and a back surface field (BSF) layer, respectively. Transparent conductive oxide (TCO) layers are formed on both sides to ensure good conductive anti-reflective coating. In the end, front- and back-side electrodes are formed to enable electrical connections.

### Fabrication Method I

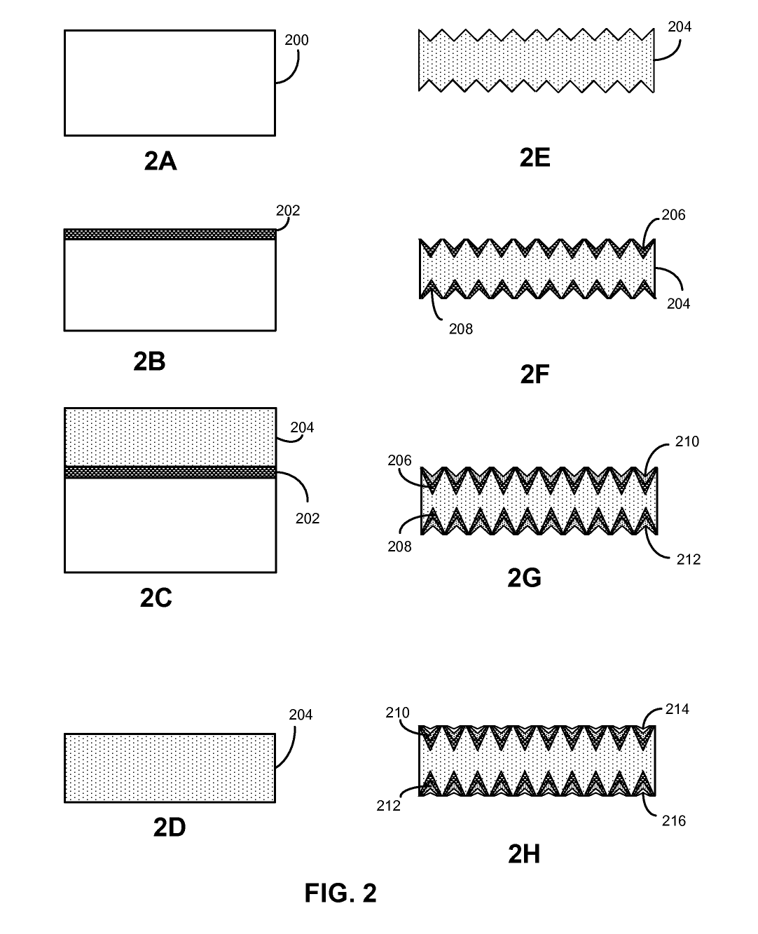

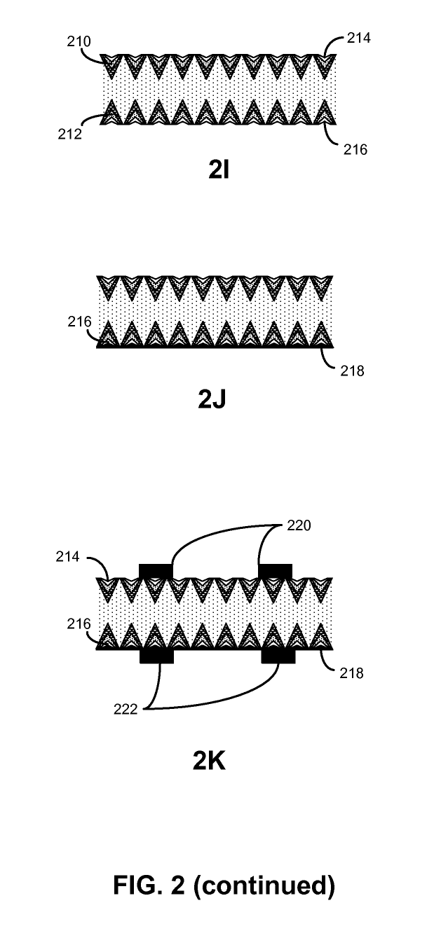

Either n- or p-type doped MG-Si wafers can be used to build the high-efficiency double-sided heterojunction solar cell. In one embodiment, an n-type doped MG-Si wafer is selected. FIG. 2 presents a diagram illustrating the process of fabricating a double-sided heterojunction solar cell in accordance with an embodiment of the present invention.

In operation 2A, an MG-Si substrate 200 is prepared. Because MG-Si is much cheaper than solar grade or semiconductor grade c-Si, solar cells based on MG-Si substrates have a significantly lower manufacture cost. The purity of MG-Si is usually between 98% and 99.99%. To ensure high efficiency of the subsequently fabricated solar cell, the starting MG-Si substrate ideally has a purity of 99.9% or better. The resistivity of the MG-Si substrate is typically in, but not limited to, the range between 0.001 Ohm-cm and 0.1 Ohm-cm. In general, a low-cost MG-Si wafer needs further purification in an atmosphere including H₂ and HCl gases at high temperature (greater than 800° C.) prior to the epitaxial (EPI) growth process. In one embodiment, MG-Si substrate 200 is treated at a temperature between 1100° C. and 1250° C. in a chemical-vapor-deposition (CVD) chamber filled with H₂ in order to remove native silicon-oxide in the substrate. Afterwards, at approximately the same temperature, HCl gas is introduced inside the CVD chamber to leach out any residual metal impurities from MG-Si substrate 200, thus further preventing the impurities from diffusing into the subsequently grown c-Si thin films. Due to the fact that metal impurities, such as iron, have a high diffusion coefficient at this temperature, the metal impurities tend to migrate to the surface of substrate 200, and react with the HCl gas to form volatile chloride compounds. The volatile chloride compounds can be effectively purged from the chamber using a purge gas, such as H₂. Note that the metal-impurity leaching process can be carried out either in the CVD chamber, which is subsequently used for the growth of crystalline-Si thin films, or in another stand-alone furnace. In addition, the surface of MG-Si substrate 200 is chemically polished to ensure subsequent high-quality EPI growth.

In operation 2B, a thin layer of heavily doped c-Si, layer 202, is epitaxially grown on MG-Si substrate 200. In one embodiment, heavily doped c-Si EPI layer 202 is formed using a chemical-vapor-deposition (CVD) epitaxial process. Various types of Si compounds, such as SiH₄, SiH₂Cl₂, and SiHCl₃, can be used as a precursor in the CVD process to form heavily doped c-Si EPI layer 202. In one embodiment, SiHCl₃ (TCS) is used due to its abundance and low cost. The thickness of heavily doped c-Si EPI layer 202 can be between 1 μm and 5 μm. The doping type of heavily doped c-Si EPI layer 202 is the same as the doping type of MG-Si substrate 200. In one embodiment, heavily doped c-Si EPI layer 202 is n-type doped. The doping concentration of heavily doped c-Si EPI layer 202 can be between 1×10¹⁷/cm³ and 1×10²⁰/cm³. The doping level should not exceed a maximum limit, which may cause misfit dislocations in the film. Heavily doped c-Si EPI layer 202 can act as a back surface field (BSF), an impurity barrier, and a contaminant getter layer for reducing electron-hole recombination at the surface of the subsequently grown base film.

In operation 2C, a layer of lightly doped c-Si is epitaxially grown on heavily doped c-Si EPI layer 202 to form a base layer 204. The process used for the growth of base layer 204 is similar to the one used for the growth of heavily doped c-Si EPI layer 202. In one embodiment, a CVD EPI process is used to form base layer 204. The thickness of base layer 204 can be between 20 μm and 100 μm. The doping type of base layer 204 is the same as the doping type of MG-Si substrate 200 and heavily doped c-Si EPI layer 202. In one embodiment, base layer 204 is n-type doped, which can provide better carrier lifetime, higher V_{oc}, and higher solar cell efficiency. The doping concentration of base layer 204 can be between 1×10¹⁵/cm³ and 1×10¹⁷/cm³.

After EPI growth of base layer 204, in operation 2D, MG-Si substrate 200 and heavily doped c-Si EPI layer 202 are removed. Various techniques can be used to remove MG-Si substrate 200 and heavily doped c-Si EPI layer 202, including, but not limited to: mechanical grinding, chemical wet etching, dry etching, and chemical mechanical polishing. In one embodiment, a mechanical backgrinding method is used to remove MG-Si substrate 200 and heavily doped c-Si EPI layer 202. Subsequently, a wet chemical etching process is used to remove all backgrind damage which may result in increased minority-carrier recombination, thus degrading the solar cell performance. Solutions used in the wet chemical etching include, but are not limited to: sodium hydroxide (NaOH), tetramethylammonium hydroxide (TMAH), and a mixture of nitric acid and hydrofluoric acid (HNO₃:HF).

In operation 2E, the front and back surfaces of base layer 204 are textured to maximize light absorption inside the solar cell, thus further enhancing efficiency. The surface texturing can be performed using various etching techniques, including dry plasma etching and wet chemical etching. The etchants used in the dry plasma etching include, but are not limited to: SF₆, F₂, and NF₃. The wet chemical etchant can be an alkaline solution. The shapes of the surface texture can be pyramids or inverted pyramids, which are randomly or regularly distributed on the front and back surfaces of base layer 204.

In operation 2F, ultra-thin passivation layers 206 and 208 are deposited on the front and back surfaces of base layer 204. Note that, prior to the deposition of passivation layers 206 and 208, the front and back surfaces of base layer 204 are carefully cleaned to ensure good deposition quality. Passivation layers 206 and 208 can significantly reduce the density of surface minority-carrier recombination via hydrogenation passivation of surface defect states, as well as by the built-in heterojunction bandgap offset, hence resulting in higher solar cell efficiency. Passivation layers 206 and 208 can be formed using different materials such as intrinsic a-Si or silicon-oxide (SiOₓ). Techniques used for forming passivation layers 206 and 208 include, but are not limited to: PECVD, sputtering, and electron beam (e-beam) evaporation. The thickness of passivation layers 206 and 208 can be between 2 nm and 8 nm. Note that such thickness is thin enough to allow tunneling of majority carriers, thus ensuring low series resistance of the solar cell.

In operation 2G, heavily doped a-Si layers are deposited on the surfaces of passivation layers 206 and 208 to form a front-side emitter layer 210 and a BSF layer 212. The emitter layer can be p-type doped, while the BSF layer can be n-type doped. In one embodiment, front-side emitter layer 210 is p-type doped, and BSF layer 212 is n-type doped. The doping concentration of emitter layer 210 and BSF layer 212 can be between 1×10¹⁷/cm³ and 1×10²⁰/cm³. The thickness of emitter layer 210 and BSF layer 212 can be between 5 nm and 50 nm. The ultra-thin a-Si layer stack, which includes the passivation (intrinsic a-Si) layer and the heavily doped a-Si layer, on each side of base layer 204 can improve the absorption efficiency of short wavelength incident light of the solar cell, thus leading to higher efficiency.

In operation 2H, transparent conductive oxide (TCO) layers are deposited on the surfaces of emitter layer 210 and BSF layer 212 to form conductive anti-reflection layers 214 and 216. Examples of TCO include, but are not limited to: indium-tin-oxide (ITO), tin-oxide (SnOₓ), aluminum doped zinc-oxide (ZnO:Al or AZO), or gallium doped zinc-oxide (ZnO:Ga). The thicknesses for the TCO layers are between 750 Å and 850 Å, and the sheet resistance for the TCO layers needs to be less than 65 Ohm-cm in order to ensure good conductive anti-reflective coating. In addition, an ohmic contact between the heavily doped a-Si layer and the TCO layer is made by ensuring reasonable work function matching.

In operation 2I, an edge isolation process is performed to each individual solar cell to ensure electrical insulation among emitter layer 210, BSF layer 212, and base layer 204. The edge isolation can be done using at least one of the following techniques: chemical wet etching, plasma dry etching, and laser scribing.

In operation 2J, back-side electrode 218 is formed on the surface of TCO layer 216. In one embodiment, back-side electrode 218 is a full back contact made of Al, which is sputtered to the surface of TCO layer 216 to simulate a back reflector. The function of the back reflector is to reflect the longer wavelength (greater than 900 nm) light back into base layer 204, thus increasing the effective lightpath, which directly translates to larger J_{sc}. The thickness of Al back-side electrode can be between 0.2 μm and 2 μm.

In operation 2K, front-side electrode grid 220 is formed on the surface of TCO layer 214 to complete the front-side heterojunction. In the same operation, metal strips 222 are also deposited on the back side of the solar cell to complete the back-side heterojunction. In one embodiment, front-side electrode grid 220 and the back-side metal strips are made of Ag. Various metal deposition techniques can be used in operation 2K, including, but not limited to: screen printing of Ag paste, inkjet or aerosol printing of Ag ink, and e-beam evaporation. It is important to ensure that the Ag fingers on the front side of the solar cell have a high aspect ratio in order to obtain minimal resistivity and shading.

### Fabrication Method II

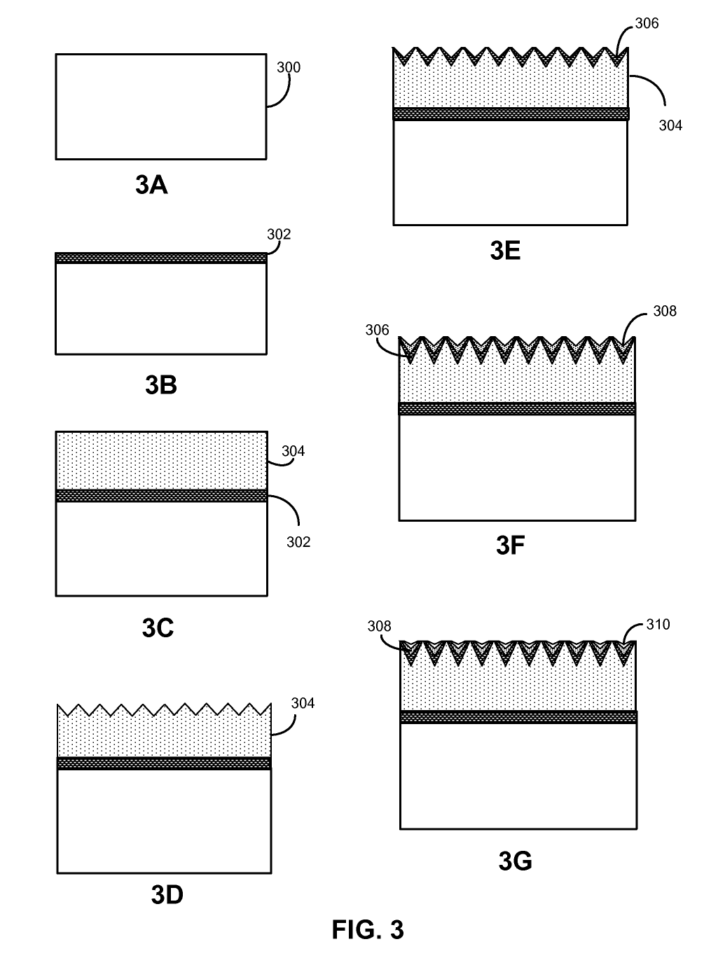

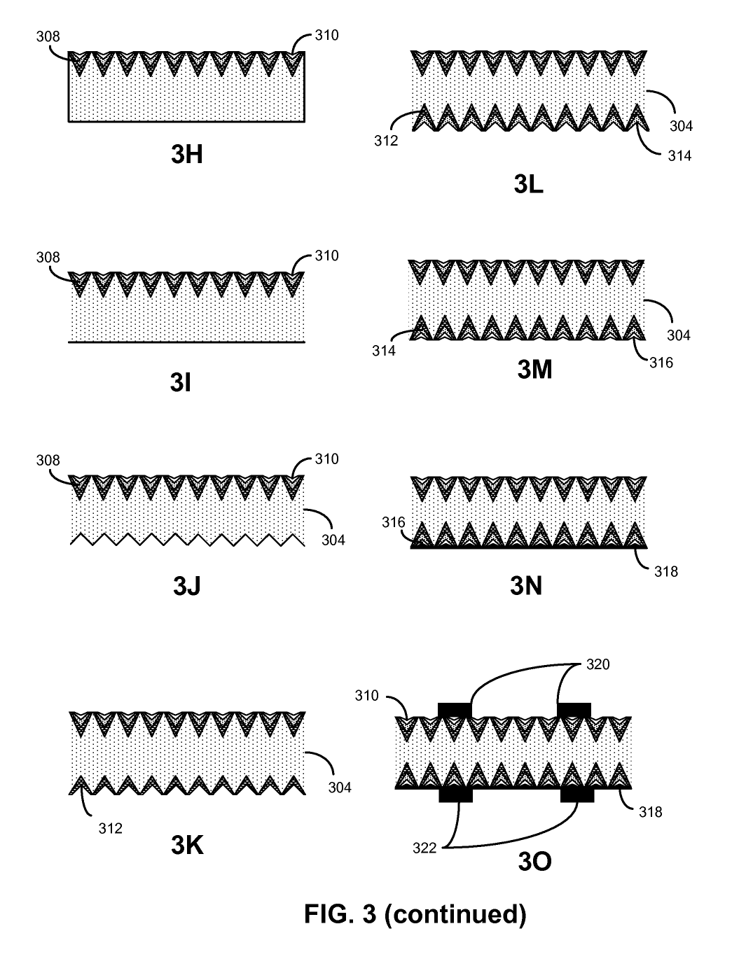

FIG. 3 presents a diagram illustrating the process of fabricating a double-sided heterojunction solar cell in accordance with an embodiment of the present invention.

In operation 3A, an MG-Si substrate 300 is prepared using a process similar to that of operation 2A.

In operation 3B, a thin layer of heavily doped c-Si, layer 302, is epitaxially grown on MG-Si substrate 300. The process used for the growth of heavily doped c-Si EPI layer 302 is similar to that used for the growth of heavily doped c-Si EPI layer 202.

In operation 3C, a layer of lightly doped c-Si is epitaxially grown on heavily doped c-Si EPI layer 302 to form a base layer 304. The process used for the growth of base layer 304 is similar to the one used for the growth of base layer 204.

In operation 3D, the front surface of base layer 304 is textured using a process similar to the one used in operation 2E.

In operation 3E, an ultra-thin amorphous Si or SiOx passivation layer 306 is deposited on the front surface of base layer 304 using a process similar to the one used in operation 2F.

In operation 3F, a heavily doped a-Si layer is deposited on the surface of passivation layer 306 to form a front-side emitter layer 308. The process used to form front-side emitter layer 308 is similar to the one used in operation 2G.

In operation 3G, a transparent conductive oxide (TCO) layer is deposited on top of front-side emitter layer 308 to form a front-side conductive anti-reflection layer 310. The process used to form front-side conductive anti-reflective layer 310 is similar to the one used in operation 2H.

In operation 3H, MG-Si substrate 300 and heavily doped c-Si EPI layer 302 are removed using a process similar to the one used in operation 2D. Note that, prior to the removal of MG-Si substrate 300 and heavily doped c-Si EPI layer 302, the front surface of the solar cell is protected via encapsulation in adhesive polymer, such as ethylene vinyl acetate (EVA), or a temporary protective coating, such as resin and glue. The encapsulation of the front surface maintains the quality of the front layers during the subsequent backgrinding process, backgrind damage removal etch, the back-side texturing, and the cleaning process.

In operation 3I, a wet chemical etching process is used to remove all backgrind damage on the back surface. In addition, edge isolation is performed.

In operation 3J, the back surface of base layer 304 is textured using a process similar to the one used in operation 2E.

In operation 3K, an ultra-thin amorphous Si or SiOx passivation layer 312 is deposited on the back surface of base layer 304 using a process similar to that of operation 2F.

In operation 3L, a heavily doped a-Si layer is deposited on the surface of passivation layer 312 to form a BSF layer 314. The process used to form the BSF layer 314 is similar to the one used in operation 2G.

In operation 3M, a transparent conductive oxide (TCO) layer is deposited on the surface of BSF layer 314 to form a conductive anti-reflection layer 316. The process used to form the conductive anti-reflective layer 316 is similar to the one used in operation 2H.

In operation 3N, back-side electrode 318 is formed on the surface of TCO layer 316 using a process similar to the one used in operation 2J.

In operation 3O, a front-side electrode grid 320 is formed on the surface of TCO layer 310 to complete the front-side heterojunction. In the same operation, metal strips 322 are also deposited on the back side of the solar cell to complete the back-side heterojunction. The process used in operation 3O is similar to the one used in operation 2K.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A method for fabricating a double-sided heterojunction solar cell, comprising:
depositing a layer of heavily doped crystalline-Si (c-Si) on the surface of a metallurgical-grade silicon (MG-Si) substrate;
epitaxially forming a layer of lightly doped c-Si on the surface of the heavily doped c-Si layer;
removing the MG-Si substrate and the heavily doped c-Si layer;
forming a front-side passivation layer on the front side of the lightly doped c-Si layer;
forming a back-side passivation layer on the back side of the lightly doped c-Si layer;
forming a front-side emitter on the front-side passivation layer;
forming a back surface field (BSF) layer on the back-side passivation layer;
forming a front-side electrode grid; and
forming a back-side electrode.

2. The method of claim 1, further comprising texturing at least one surface of the lightly doped c-Si layer.

3. The method of claim 1, wherein the MG-Si substrate is removed using one or more of the following techniques:
mechanical grinding;
chemical wet etching;
dry etching; and
chemical mechanical polishing.

4. The method of claim 1, further comprising forming a transparent conductive oxide (TCO) layer on the front-side emitter and/or the BSF layer.

5. The method of claim 1, wherein the passivation layers comprise intrinsic amorphous Si (a-Si) or silicon oxide (SiOₓ).

6. The method of claim 1, wherein the thickness of the passivation layers is between 2 nm and 8 nm.

7. The method of claim 1, wherein the emitter and/or the BSF layer comprise heavily doped a-Si.

8. The method of claim 7, wherein the thickness of the a-Si emitter and/or the BSF layer is between 5 nm and 50 nm, and wherein the doping concentration of the heavily doped a-Si is between 1×10¹⁷/cm³ and 1×10²⁰/cm³.

9. The method of claim 1, wherein the lightly doped c-Si layer is deposited using a chemical-vapor-deposition (CVD) technique, wherein the thickness of the lightly doped c-Si layer is between 20 μm and 100 μm, and wherein the doping concentration for the lightly doped c-Si layer is between 1×10¹⁵/cm³ and 1×10¹⁷/cm³.

10. The method of claim 1, wherein the lightly doped c-Si layer is n-type doped, and wherein the front-side emitter and the BSF layer are doped with different types of dopants.

11. The method of claim 1, wherein the heavily doped c-Si layer acts as an impurity getter layer, wherein the heavily doped c-Si layer is deposited using a chemical-vapor-deposition (CVD) technique, wherein the thickness of the heavily doped c-Si layer is between 1 μm and 5 μm, and wherein the doping concentration for the heavily doped c-Si layer is between 1×10¹⁷/cm³ and 1×10²⁰/cm³.

12. The method of claim 1, wherein the front-side and the back-side passivation layers are formed in one step.

13. The method of claim 1, wherein the front-side emitter and the BSF layer are formed in one step.

14. A double-sided heterojunction solar cell, comprising:
a lightly doped epitaxial crystalline Si (c-Si) base layer;
a front-side passivation layer situated on the front side of the lightly doped epitaxial c-Si base layer;
a back-side passivation layer situated on the back side of the lightly doped epitaxial c-Si base layer;
a front-side emitter situated on the surface of the front-side passivation layer;
a back surface field (BSF) layer situated on the surface of the back-side passivation layer;
a front-side electrode; and
a back-side electrode.

15. The solar cell of claim 14, wherein at least one surface of the lightly doped epitaxial c-Si layer is textured.

16. The solar cell of claim 14, further comprising at least one transparent conductive oxide (TCO) layer situated on the surface of the front-side emitter and/or the surface of the BSF layer.

17. The solar cell of claim 14, wherein the passivation layers comprise intrinsic amorphous Si (a-Si) or silicon oxide (SiOₓ).

18. The solar cell of claim 14, wherein the thickness of the passivation layers is between 2 nm and 8 nm.

19. The solar cell of claim 14, wherein the emitter and/or the BSF layer comprise heavily doped a-Si.

20. The solar cell of claim 19, wherein the thickness of the a-Si emitter and/or the BSF layer is between 5 nm and 50 nm, and wherein the doping concentration of the heavily doped a-Si is between 1×10¹⁷/cm³ and 1×10²⁰/cm³.

21. The solar cell of claim 14, wherein the lightly doped epitaxial c-Si layer is deposited using a chemical-vapor-deposition (CVD) technique, wherein the thickness of the lightly doped c-Si layer is between 20 μm and 100 μm, and wherein the doping concentration for the lightly doped c-Si layer is between 1×10¹⁵/cm³ and 1×10¹⁷/cm³.

22. The solar cell of claim 14, wherein the lightly doped c-Si layer is n-type doped, and wherein the front-side emitter and the BSF layer are doped with different types of dopants

23. The solar cell of claim 14, wherein the front-side and the back-side passivation layers are formed in one step.

24. The solar cell of claim 14, wherein the front-side emitter and the BSF layer are formed in one step.

25. The solar cell of claim 14, wherein the lightly doped epitaxial c-Si layer is epitaxially grown on a metallurgical-grade Si (MG-Si) substrate, which is subsequently removed using a mechanical grinding technique.
